(19) United States
(12) Patent Application Publication
(10) Pub. No.: US 2023/0420343 A1
(43) Pub. Date: Dec. 28, 2023

(54) PACKAGE STRUCTURE AND METHOD FOR MANUFACTURING PACKAGE STRUCTURE

(71) Applicant: CHANGXIN MEMORY TECHNOLOGIES, INC., Hefei City (CN)

(72) Inventor: Huifang DAI, Hefei City (CN)

(73) Assignee: CHANGXIN MEMORY TECHNOLOGIES, INC., Hefei City (CN)

(21) Appl. No.: 18/166,473

(22) Filed: Feb. 8, 2023

Related U.S. Application Data
(63) Continuation of application No. PCT/CN2022/108351, filed on Jul. 27, 2022.

(30) Foreign Application Priority Data
Jun. 27, 2022 (CN) 202210745228.8

(51) Int. Cl. H01L 23/498; H05K 1/11; H05K 3/34; H01L 23/00

(52) U.S. Cl. CPC H01L 23/49811; H05K 1/111; H05K 3/3457; H01L 24/11; H01L 24/13; H05K 2201/0367; H05K 2203/054; H01L 2224/1162; H01L 2224/1308

(57) ABSTRACT

A package structure includes: a substrate, where a plurality of welding pads are disposed on a surface of the substrate, each of the plurality of welding pads includes a bottom layer welding pad and a top layer welding pad which are stacked onto one another, and at least two of peripheral surfaces of the top layer welding pad are protruded relative to peripheral surfaces of the bottom layer welding pad; a chip located on the substrate and spaced apart from the substrate; and a plurality of solder balls, where the plurality of solder balls are welded to the substrate and the chip, and the plurality of solder balls wrap the top layer welding pads.

### CROSS-REFERENCE TO RELATED APPLICATIONS

This is a continuation of International Patent Application No. PCT/CN2022/108351 filed on Jul. 27, 2022, which claims priority to Chinese Patent Application No. 202210745228.8 filed on Jun. 27, 2022. The disclosures of the above-referenced applications are hereby incorporated by reference in their entirety.

### BACKGROUND

A package structure includes a substrate and a chip welded on the substrate. The substrate can provide the effects of electric connection, protection, support, heat dissipation, assembly and the like for the chip, so that the purposes of multi-pin, reduction of the volume of the package structure, improvements on electric performance and heat dissipation, ultrahigh density or multi-chip modularization are achieved.

### SUMMARY

Embodiments of the disclosure belong to the field of package, and particularly relate to a package structure and a method for manufacturing a package structure.

The embodiments of the disclosure provide a package structure and a method for manufacturing a package structure.

According to some embodiments of the disclosure, an aspect of the embodiments of the disclosure provides a package structure. The package structure includes: a substrate, where at least one welding pad is disposed on a surface of the substrate, the at least one welding pad including a bottom layer welding pad and a top layer welding pad which are stacked onto one another, and at least two of peripheral surfaces of the top layer welding pad are protruded relative to peripheral surfaces of the bottom layer welding pad; a chip located on the substrate and spaced apart from the substrate; and at least one solder ball, where the at least one solder ball is welded to the substrate and the chip, and the at least one solder ball wraps the top layer welding pad.

According to some embodiments of the disclosure, another aspect of the embodiments of the disclosure provides a method for manufacturing a package structure, which includes the following operations: a substrate is provided, and a plurality of welding pads are formed on a surface of the substrate, where each of the plurality of welding pads includes a bottom layer welding pad and a top layer welding pad which are stacked onto one another, and at least two of peripheral surfaces of the top layer welding pad is protruded relative to peripheral surfaces of the bottom layer welding pad; a chip is provided; and the chip is welded to the plurality of welding pads through a plurality of solder balls, where each of the plurality of solder balls wraps a respective one of the top layer welding pads.

### BRIEF DESCRIPTION OF THE DRAWINGS

The accompanying drawings, which are incorporated in and constitute a part of this specification, illustrate the embodiments consistent with the disclosure and, together with the specification, serve to explain the principles of the disclosure. Obviously, the drawings described below are only some embodiments of the disclosure, and other drawings can further be obtained by those of ordinary skill in the art according to the drawings without creative work.

FIG. 1 illustrates a schematic diagram of a package structure.

FIG. 2 illustrates a schematic diagram of a package structure provided by an embodiment of the disclosure.

FIG. 3 illustrates a schematic diagram of another package structure provided by an embodiment of the disclosure.

FIG. 4 illustrates a schematic diagram of still another package structure provided by an embodiment of the disclosure

FIG. 5 illustrates a cross-sectional view of a welding pad provided by an embodiment of the disclosure.

FIG. 6 illustrates a top view of a welding pad provided by an embodiment of the disclosure.

FIG. 7 illustrates a top view of another welding pad provided by an embodiment of the disclosure.

FIG. 8 illustrates a first schematic diagram corresponding to operations in a method for manufacturing a package structure provided by another embodiment of the disclosure.

FIG. 9 illustrates a second schematic diagram corresponding to operations in a method for manufacturing a package structure provided by another embodiment of the disclosure.

FIG. 10 illustrates a third schematic diagram corresponding to operations in a method for manufacturing a package structure provided by another embodiment of the disclosure.

FIG. 11 illustrates a fourth schematic diagram corresponding to operations in a method for manufacturing a package structure provided by another embodiment of the disclosure.

FIG. 12 illustrates a fifth schematic diagram corresponding to operations in a method for manufacturing a package structure provided by another embodiment of the disclosure.

FIG. 13 illustrates a sixth schematic diagram corresponding to operations in a method for manufacturing a package structure provided by another embodiment of the disclosure.

FIG. 14 illustrates a seventh schematic diagram corresponding to operations in a method for manufacturing a package structure provided by another embodiment of the disclosure.

FIG. 15 illustrates a first schematic diagram corresponding to operations in a method for manufacturing another package structure provided by another embodiment of the disclosure.

FIG. 16 illustrates a second schematic diagram corresponding to operations in a method for manufacturing another package structure provided by another embodiment of the disclosure.

FIG. 17 illustrates a third schematic diagram corresponding to operations in a method for manufacturing another package structure provided by another embodiment of the disclosure.

FIG. 18 illustrates a fourth schematic diagram corresponding to operations in a method for manufacturing another package structure provided by another embodiment of the disclosure.

FIG. 19 illustrates a fifth schematic diagram corresponding to operations in a method for manufacturing another package structure provided by another embodiment of the disclosure.

FIG. 20 illustrates a sixth schematic diagram corresponding to operations in a method for manufacturing another package structure provided by another embodiment of the disclosure.

### DETAILED DESCRIPTION

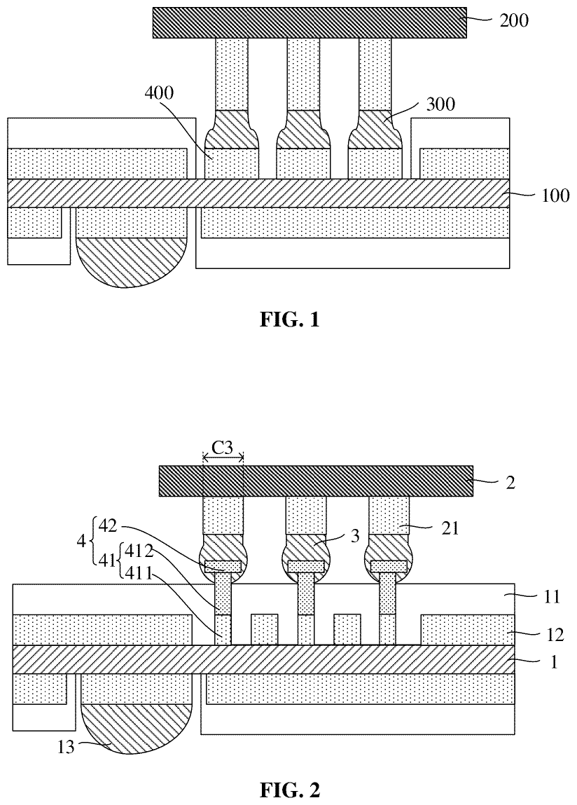

With reference to FIG. 1, it is found that a welding pad 400 on a substrate 100 is generally a planar welding pad, that is, one planar surface of the welding pad 400 is connected to a solder ball 300. Since the bonding strength of one planar surface to the solder ball 300 is poor, the reliability of welding is poor. In addition, in order to ensure the bonding strength between the solder ball 300 and the welding pad 400, the dimension of the welding pad 400 needs to be increased. Therefore, the welding pad 400 occupies a large area on the substrate 100, and thus may occupy the spatial positions of other elements on the surface of the substrate 100.

The embodiments of the disclosure provide a package structure. Each of a plurality of welding pads of the package structure includes a bottom layer welding pad and a top layer welding pad which are stacked onto one another, and at least two of peripheral surfaces of the top layer welding pad are protruded relative to peripheral surfaces of the bottom layer welding pad. That is, the bottom layer welding pad is connected to a surface of the substrate and is small in the dimension, so that the space of the substrate can be saved. The dimension of the top layer welding pad is larger, so that the contact area of the top layer welding pad with the solder ball can be increased. In addition, the peripheral surfaces of the top layer welding pad are disposed in a protruding manner, so that each of a plurality of solder balls can wrap the top surface, the peripheral surfaces, and the bottom surface of the protruding part of the top layer welding pad, then three-dimensional wrapping can be formed, and thus the bonding strength can be increased.

The embodiments of the disclosure will be described in detail below with reference to the drawings. However, it will be appreciated by those of ordinary skill in the art that in the embodiments of the disclosure, numerous technical details are set forth in order to provide a better understanding of the embodiments of the disclosure. However, the technical solutions claimed in the embodiments of the disclosure may be implemented even without these technical details and various changes and modifications based on the following embodiments.

As shown in FIG. 2 to FIG. 7, an embodiment of the disclosure provides a package structure. The package structure includes: a substrate 1, where a welding pad 4 is disposed on a surface of the substrate 1, the welding pad 4 includes a bottom layer welding pad 41 and a top layer welding pad 42 which are stacked onto one another, and at least two of peripheral surfaces of the top layer welding pad 42 are protruded relative to peripheral surfaces of the bottom layer welding pad 41; a chip 2, where the chip 2 is located on the substrate 1 and is spaced apart from the substrate 1; and a solder ball 3, where the solder ball 3 is welded to the substrate 1 and the chip 2, and the solder ball 3 wraps the top layer welding pad 42.

That is, the dimension of the bottom layer welding pad 41 is smaller, and is directly connected to the surface of the substrate 1. Therefore, the occupied area on the surface of the substrate 1 can be reduced, thereby reducing the dimension of the package structure. In addition, the bottom layer welding pad 41 with a smaller dimension can expose a part of a bottom surface of the top layer welding pad 42, so that the solder ball 3 can wrap a top surface, the peripheral surfaces, and the part of the bottom surface of the top layer welding pad 42. Compared with planar surface contact, three-dimensional wrapping can improve the welding strength, so that the reliability of the package structure is improved.

The package structure will be described in detail below with reference to the drawings.

With reference to FIG. 2 to FIG. 4, the substrate 1 can realize transmission of current and signals between the chip 2 and the outside, can mechanically protect and support the chip 2, and can also help the chip 2 to dissipate heat. Exemplarily, the substrate 1 may be an insulating substrate, such as a ceramic substrate or an organic substrate. In some embodiments, elements may be disposed on both a front surface and a back surface of the substrate 1. For example, a welding block 13 may also be disposed on the back surface of the substrate 1, and the welding block 13 is connected to an external component, so that the substrate 1 is disposed on the external component.

A large number of microelectronic components and parts such as transistors and capacitors are integrated in the chip 2. Exemplarily, the chip 2 may be a memory chip, such as a dynamic random access memory chip. The chip 2 is connected to the substrate 1 by welding. Specifically, welding compositions may include a solder and a flux. The flux may adopt active agents such as rosin and resin, and the welding process can be promoted by the flux. The solder may adopt a low-melting metal, such as tin. In the welding process, the solder is heated to be melted and diffused, to wrap the top surface, the peripheral surfaces and the bottom surface of the protruding part of the top layer welding pad 42, so that the chip 2 is connected to the welding pad 4, and the permanently connected welding ball 3 is formed after the solder is cooled.

With reference to FIG. 2 to FIG. 4, a support bump 21 is disposed on a surface of the chip 2 facing toward the substrate 1, and the welding ball 3 is connected to the support bump 21. That is, the support bump 21 is electrically connected to the elements in the chip 2 and is capable to provide welding positions for the chip 2. Exemplarily, the material of the support bump 21 may be a low-resistance metal such as copper and aluminum.

With reference to FIG. 2 to FIG. 5, in some embodiments, the width C3 of the support bump 21 is greater than the width C2 of the top layer welding pad 42. The width direction of the support bump 21 and the width direction of the top layer welding pad 42 are parallel to a protruding direction of the top layer welding pad 42 in which the top layer welding pad 42 is protruded. It is to be noted that the dimension of the support bump 21 is relatively large, so that the contact area of the support bump 21 and the solder ball 3 can be increased, and thus the fastness of welding can be increased. In addition, the large dimension of the support bump 21 can also provide a certain margin for alignment errors between the chip 2 and the substrate 1. That is, the welding strength of the chip 2 and the substrate 1 can be guaranteed even if there is a certain alignment error between the chip 2 and the substrate 1.

Specifically, the difference between the width C3 of the support bump 21 and the width C2 of the top layer welding pad 42 is greater than 10 um, for example, the difference between the width of the support bump and the width of the top layer welding pad is 11 um, 12 um or 15 um. When the difference between the width of the support bump and the width of the top layer welding pad is within the above range, a proper welding area can be obtained, so that the fastness of welding can be improved. It is to be noted that the width C3 of the support bump 21 should not be too large, in order to ensure that a suitable spacing is formed between any adjacent support bumps 21 of a plurality of support bumps 21 to prevent the bridging of the adjacent support bumps 21. Exemplarily, the difference between the width C3 of each of the plurality of support bumps 21 and the width C2 of the top layer welding pad 42 may be less than 25 um.

The protruding type of the top layer welding pad 42 will be described in detail below.

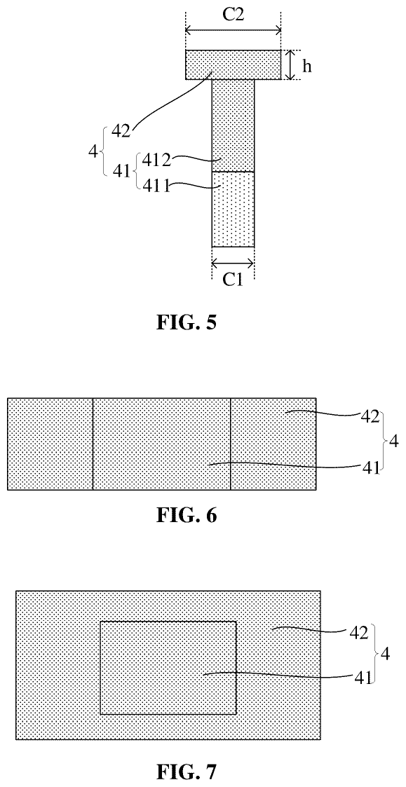

FIG. 6 illustrates a top view of a welding pad 4. With reference to FIG. 6, in some embodiments, two of the peripheral surfaces of the top layer welding pad 42 is protruded relative to two of the peripheral surfaces of the bottom layer welding pad 41. That is, another two of the peripheral surfaces of the top layer welding pad 42 may also be aligned with another two of the peripheral surfaces of the bottom layer welding pad 41. Exemplarily, the peripheral surfaces of the top layer welding pad 42 located on two opposite sides thereof are protruded relative to the peripheral surfaces of the bottom layer welding pad 41 located on two opposite sides thereof. That is, the welding pad 4 may be T-shaped. In this way, it can be guaranteed that the protruding direction of the top layer welding pad 42 is roughly symmetrical, thus the uniformity of wrapping the top layer welding pad 42 by the solder ball 3 can be improved, and then the bonding strength is improved.

For example, the orthographic projection of the top layer welding pad 42 on the surface of the substrate 1 may be rectangular, and the orthographic projection of the bottom layer welding pad 41 on the surface of the substrate 1 may be rectangular. That is, the peripheral surfaces of the top layer welding pad 42 and the peripheral surfaces of the bottom layer welding pad 41 may each include four side surfaces. Two opposite side surfaces of the top layer welding pad 42 are aligned with two opposite side surfaces of the bottom layer welding pad 41, and two other opposite side surfaces of the top layer welding pad 42 are protruded relative to two other opposite side surfaces of the bottom layer welding pad 41. In addition, the orthographic projection of the top layer welding pad 42 on the surface of the substrate 1 and the orthographic projection of the bottom layer welding pad 41 on the surface of the substrate 1 may also be in the shape of a circle, an ellipse or a trapezoid.

FIG. 7 illustrates a top view of another welding pad 4. With reference to FIG. 7, in some other embodiments, all the peripheral surfaces of the top layer welding pad 42 are protruded relative to all the peripheral surfaces of the bottom layer welding pad 41. That is, the orthographic projection of the bottom layer welding pad 41 on the surface of the substrate 1 is located within the orthographic projection of the top layer bonding pad 42 on the surface of the substrate 1, and the edges of the orthographic projection of the bottom layer welding pad on the surface of the substrate are spaced apart from the edges of the orthographic projection of the top layer bonding pad on the surface of the substrate. Therefore, the solder ball 3 can wrap around the exposed bottom surface of the top layer welding pad 42, which facilitates improving the welding strength.

With reference to FIG. 6 to FIG. 7, the orthographic projection of the bottom layer welding pad 41 on the surface of the substrate 1 is located at the center within the orthographic projection of the top layer bonding pad 42 on the surface of the substrate 1. That is, the center of the orthographic projection of the bottom layer welding pad 41 coincides with the center of the orthographic projection of the top layer bonding pad 42. Therefore, the uniformity of wrapping the top layer welding pad 42 by the solder ball 3 can be improved, and further, the bonding strength of the top layer welding pad 42 and the solder ball 3 at different contact positions can be balanced, and the welding reliability is improved. Exemplarily, the peripheral surfaces of the top layer welding pad 42 may be protruded with the same degree in different directions. That is, the orthographic projection of the top layer welding pad 42 on the surface of the substrate 1 and the orthographic projection of the bottom layer welding pad 41 on the surface of the substrate 1 can form an annular structure, and the annular structure has uniform annular width.

With further reference to FIG. 2 to FIG. 5, the relationship between the dimension of the top layer welding pad 42 and the dimension of the bottom layer welding pad 41 will be described in detail below.

In some embodiments, the difference between the width C2 of the top layer welding pad 42 and the width C1 of the bottom layer welding pad 41 is greater than 10 um, for example, the difference between the width C2 of the top layer welding pad 42 and the width C1 of the bottom layer welding pad 41 is greater than 11 um, 12 um or 15 um. The width direction of the top layer welding pad 42 and the width direction of the bottom layer welding pad 41 are parallel to a protruding direction of the top layer welding pad 42 in which the top layer welding pad 42 is protruded. In addition, the difference between the width C2 of the top layer welding pad 42 and the width Cl of the bottom layer welding pad 41 may be less than 20 um. It is to be noted that if the width C2 of the top layer welding pad 42 is too large, the solder ball 3 may be insufficient to wrap the top pad welding layer 42; and if the width C2 of the top layer welding pad 42 is too small, the support surface may be insufficient. When the difference between the width C2 of the top layer welding pad 42 and the width C1 of the bottom layer welding pad 41 is within the above range, a proper welding area can be obtained, so that the fastness of welding can be improved.

It is to be noted that if the width Cl of the bottom layer welding pad 41 is too small, it may be difficult to support the top layer welding pad 42, so that the problem of collapse or tilting of the welding pad 4 may occur. In some embodiments, the width of the bottom layer welding pad 41 is greater than 12 um, which facilitates improving the fastness of the welding pad 4.

In some embodiments, the thickness h of the top layer welding pad 42 ranges from 5 um to 10 um, for example, the thickness h may be 6 um, 8 um or 9 um. The thickness direction of the top layer welding pad 42 is perpendicular to the surface of the substrate 1.

It is be noted that if the top layer welding pad 42 is too thin, it may be difficult to support the solder ball 3; if the top layer welding pad 42 is too thick, it may be difficult for the solder to diffuse to the bottom surface of the top layer welding pad 42, i.e., the amount of the soldering tin is insufficient, and it is difficult to form three-dimensional wrapping. When the thickness of the top layer welding pad 42 is in the above range, the above two problems can be taken into account.

With reference to FIG. 2 to FIG. 4, a solder resist layer 11 is also disposed on the surface of the substrate 1. The solder resist layer 11 may be made of an insulating material such as a polymer, for preventing erroneous bridging of the elements on the substrate 1, thereby avoiding short circuits. Specifically, the bottom layer welding pad 41 penetrates through the solder resist layer 11, that is, the bottom layer welding pad 41 is located in the solder resist layer 11, to isolate other elements on the substrate 1 from the bottom layer welding pad 41.

With reference to FIG. 2 to FIG. 4, the position relationship of the solder resist layer 11 and the welding pad 4 can be described in detail below,

It is to be noted that the bottom surface of the top layer welding pad 42 is located higher than the top surface of the solder resist layer 11. That is, a certain space is reserved between the bottom surface of the top layer welding pad 42 and the top surface of the solder resist layer 11, so that the solder ball 3 can be accommodated in this space, and the solder ball 3 can form three-dimensional wrapping for the top layer welding pad 42.

For example, the difference between the height of the bottom surface of the top layer welding pad 42 and the height of the top surface of the solder resist layer 11 ranges from 3 um to 7 um, for example, this difference is 4 um, 5 um or 6 um. It is to be noted that if this difference is too small, it may be difficult to provide sufficient accommodating space for the solder ball 3, that is, it is difficult to form three-dimensional wrapping; and if this difference is too large, the process difficulty may be increased, and in addition, the fastness of the welding pad 4 is not facilitated. When this difference is within the above range, the two problems may be both taken into account.

In some embodiments, with reference to FIG. 2, the solder resist layer 11 is in contact with the bottom layer welding pad 41, i.e., a gap is absent between the solder resist layer and the bottom layer welding pad. In this way, the solder resist layer 11 can also have a certain effect of supporting the bottom layer welding pad 41, which thus can improve the fastness of the bottom layer welding pad 41.

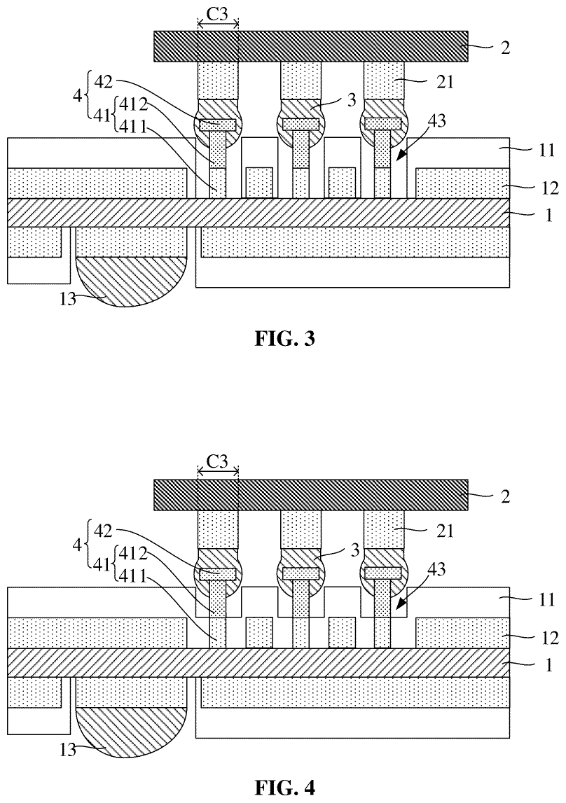

In some other embodiments, with reference to FIG. 3 to FIG. 5, a gap 43 is formed between the solder resist layer 11 and the bottom layer welding pad 41. Exemplarily, the bottom layer welding pad 41 includes a first welding pad 411 and a second welding pad 412 which are stacked onto one another, and the gap 43 is at least located between the second welding pad 412 and the solder resist layer 11. The gap 43 can play a role of accommodating the solder ball 3, so that the tin feeding amount of the welding pad 4 can be increased, and the welding strength is further improved. In addition, the gap 43 can also play the role of guiding diffusion of the solder ball 3, so that the solder ball 3 diffuse towards the peripheral surfaces of the bottom layer welding pad 41, then bridging of the solder ball 3 with other elements on the substrate 1 is prevented, and in addition, the contact area between the solder ball 3 and the peripheral surfaces of the bottom layer welding pad 41 is increased.

Specifically, with reference to FIG. 3, the gap 43 is also located between the first welding pad 411 and the solder resist layer 11, so that the accommodating space for the solder ball 3 can be increased, the solder ball 3 is concentrated on the peripheral surfaces of the welding pad 4. Therefore, the bonding strength can be improved, and connection of the solder ball with other elements can be prevented.

In some embodiments, with reference to FIG. 4, the first welding pad 411 is in contact with the solder resist layer 11, i.e., a gap 43 is absent between the first welding pad 411 and the solder resist layer 11. The solder resist layer 11 can play roles of fixing and supporting the first welding pad 411, and therefore, the stability of the first welding pad 411 can be improved.

It is to be noted that when a gap 43 is formed between the bottom layer welding pad 41 and the solder resist layer 11, the gap 43 can accommodate a certain amount of solder ball. Therefore, the difference between the height of the top surface of the solder resist layer 11 and the height of the bottom surface of the top layer welding pad 42 can be accordingly reduced, thereby saving the material of the welding pad 4 and improving the fastness of the welding pad 4.

With further reference to FIG. 3 to FIG. 4, the peripheral surfaces of the top layer welding pad 42 is protruded by a distance less than or equal to the width of the gap 43 relative to the peripheral surfaces of the bottom layer welding pad 41. In other words, the orthographic projection of the protruding peripheral surfaces of the top layer welding pad 42 on the surface of the substrate 1 is located within the orthographic projection of the gap 43 on the substrate 1. In this way, the opening through which the solder ball 3 enters into the gap 43 is enlarged, thereby enhancing the guiding effect of the gap 43, preventing the solder ball 3 from diffusing in a direction away from the welding pad 4, that is, guiding the solder ball 3 to flow into the gap 43, and thus preventing bridging of adjacent solder balls 3. In addition, due to the effect of the solder resist layer 11, it is also possible to prevent the solder ball 3 from contacting a conductive layer 12. The conductive layer 12 may be a metal layer.

With reference to FIG. 2 to FIG. 4, a plurality of conductive layers 12 are disposed on the surface of the substrate 1 and spaced apart from each other. The plurality of conductive layers 12 are disposed on the same layer as a plurality of first welding pads 411 and spaced apart from the plurality of first welding pads 411. That is, the first welding pad 411 can be formed using the process operations for the plurality of conductive layers 12, thereby facilitating simplification of the production process.

Exemplarily, each of the plurality of conductive layers 12 may be a copper layer for wiring on the surface of the substrate 1, and correspondingly, each of the plurality of first welding pads 411 may also be a copper layer. The plurality of conductive layers 12 are electrically connected to the elements on the substrate 1, and the plurality of conductive layers 12 extend in a direction parallel to the surface of the substrate 1, thereby changing the layout of the elements or leading out ports of the elements.

It is to be noted that since the bottom layer welding pad 41 has a smaller dimension than the top bottom welding pad 42, that is, the first welding pad 411 has a smaller dimension, the occupied area of the first welding pad 411 on the surface of the substrate 1 is smaller, thereby providing more spatial positions for the plurality of conductive layers 12 and increasing the number of the plurality of conductive layers 12. In addition, sufficient spatial positions can also facilitate layout of the plurality of conductive layers 12, thereby facilitating shortening of the length of the plurality of conductive layers 12 to reduce power consumption and improve signal quality.

In some embodiments, the solder resist layer 11 disposed on the surface of the substrate 1 also covers the plurality of conductive layers 12, so that bridging between the plurality of conductive layers 12 can be prevented. Specifically, the solder resist layer 11 may cover a top surface and a side surface of each of the plurality of conductive layers 12.

In some embodiments, a plurality of welding pads 4 are provided. Due to the small dimension of each of the plurality of bottom layer welding pads 41, the space on the surface of the substrate 1 is sufficient. Thus, the spacing between any adjacent bottom layer welding pads 41 of the plurality of bottom layer welding pads 41 can be increased, to prevent connection of each solder ball 3 with two welding pads 4 adjacent to each solder ball 3.

In addition, the solder resist layer 11 is also located between any adjacent bottom layer welding pads 41 of the plurality of bottom layer welding pads 41. That is, due to the small dimension of each of the plurality of bottom layer welding pads 41, it is possible to provide a spatial position for the solder resist layer 11 to prevent bridging of any adjacent welding pads 4 of the plurality of welding pads 4.

In some embodiments, at least one conductive layer 12 is disposed between any adjacent first welding pads 411 of the plurality of first welding pads 411. In other words, said conductive layer 12 can be disposed at a spatial position between any adjacent first welding pads 411 of the plurality of first welding pads 411, thereby facilitating an increase in the utilization rate of the space of the substrate 1. In this way, the spacing between any adjacent first welding pads 411 of the plurality of first welding pads 411 can be increased to prevent erroneous welding; and the number of the conductive layers 12 may also be increased. It is to be noted that the conductive layer 12 between any adjacent first pads 411 of the plurality of first welding pads 411 is covered by the solder resist layer 11, thereby preventing bridging of the plurality of conductive layers 12 with the plurality of first welding pads 411.

In conclusion, in the embodiments of the disclosure, at least two of the peripheral surfaces of the top layer welding pad 42 is protruded relative to at least two of the peripheral surfaces of the bottom layer welding pad 41. That is, a three-dimensional welding pad is adopted to replace a planar welding pad, and accordingly, planar bonding of the welding ball 3 and the welding pad 4 can be converted into three-dimensional wrapping bonding. That is, the welding strength is related not only to the size of the contact area, but also to the manner of contact. In three-dimensional wrapping, a large bonding force can be formed between the protruding part of the top layer welding pad 42 and the solder ball 3, and therefore, the welding reliability is improved. In addition, the reduction of the dimension of the bottom layer welding pad 41 can prevent the bottom layer welding pad 41 from occupying the wiring space of the substrate 1, which facilitates shortening the wiring length and improving the signal quality. In addition, due to the smaller width of the bottom layer welding pad 41, more bottom layer welding pads 41 may be disposed on the substrate 1, and thus more signal lines which may pass through the plurality of conductive layers 12 and the plurality of bottom layer welding pads 41 perpendicular to the plurality of conductive layers 12 and the plurality of bottom layer welding pads 41 (extending inwardly perpendicular to the figure) may be disposed on the substrate 1.

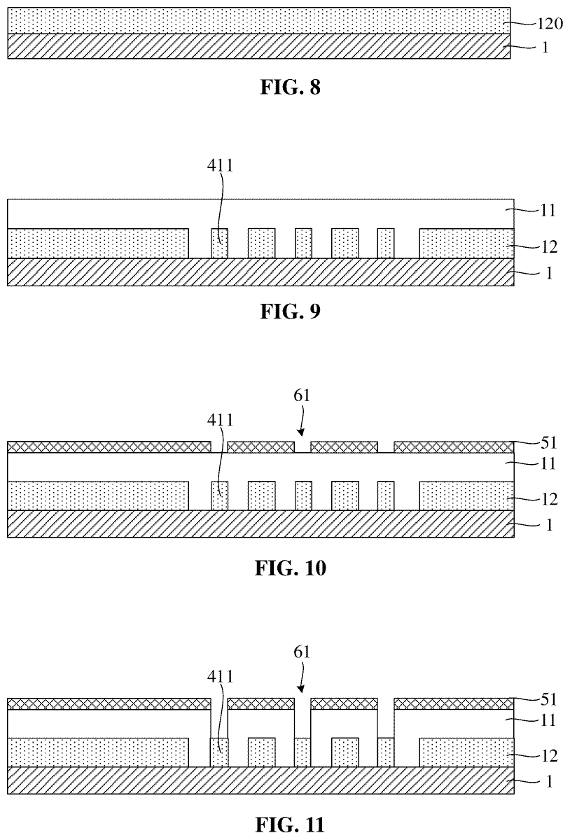

As shown in FIG. 8 to FIG. 20, another embodiment of the disclosure provides a method for manufacturing a package structure, which may be used to manufacture the package structure provided by the foregoing embodiments. For the detailed description of the packing structure, reference is made to the foregoing detailed description, which is not repeated here.

The method for manufacturing the package structure will be described in detail below with reference to the drawings.

With reference to FIG. 8, a substrate 1 is provided, and an initial conductive layer 120 is formed on a surface of the substrate 1. Exemplarily, a copper layer is plated on the surface of the substrate 1 as the initial conductive layer 120.

With reference to FIG. 9, the initial conductive layer 120 is patterned to form a plurality of first welding pads 411. Exemplarily, part of the initial conductive layer 120 is etched, where remaining parts of the initial conductive layer 120 can serve as the plurality of first welding pads 411 and the plurality of conductive layers 12. The plurality of first bonding pads 411 are configured to be welded to the chip 2 subsequently, the plurality of conductive layers 12 are configured to extend a signal line of an element, and the plurality of first welding pads 411 can also be configured to extend a signal line of an element. Exemplarily, each of the plurality of first welding pads 411 may be block-shaped, and each of the plurality of conductive layer 12 may be strip-shaped.

With further reference to FIG. 9, a solder resist layer 11 covering the plurality of first welding pads 411 is formed. In addition, the solder resist layer 11 also covers the surface of the substrate 1 and the plurality of conductive layers 12. Exemplarily, ink is applied on the substrate 1, the plurality of conductive layers 12, and the plurality of first welding pads 411 as the solder resist layer 11.

With reference to FIG. 10, a first mask layer 51 is formed on the solder resist layer 11, where the first mask layer 51 is provided with a plurality of first openings 61 directly facing toward the plurality of first welding pads 411. Exemplarily, the first mask layer 51 may be a first photoresist layer, and exposure development treatment is performed on the first photoresist layer to form the plurality of first openings 61.

With reference to FIG. 11, the solder resist layer 11 located on top surfaces of the plurality of first welding pads 411 is removed along the plurality of first openings 61. Exemplarily, the solder resist layer 11 can be made of a photosensitive material, and the solder resist layer 11 exposed by the plurality of first openings 61 reacts under illumination; and after dissolution of a developer, the solder resist layer 11 located below the plurality of first openings 61 can be removed. In other embodiments, an etching process may also be adopted to remove part of the solder resist layer 11.

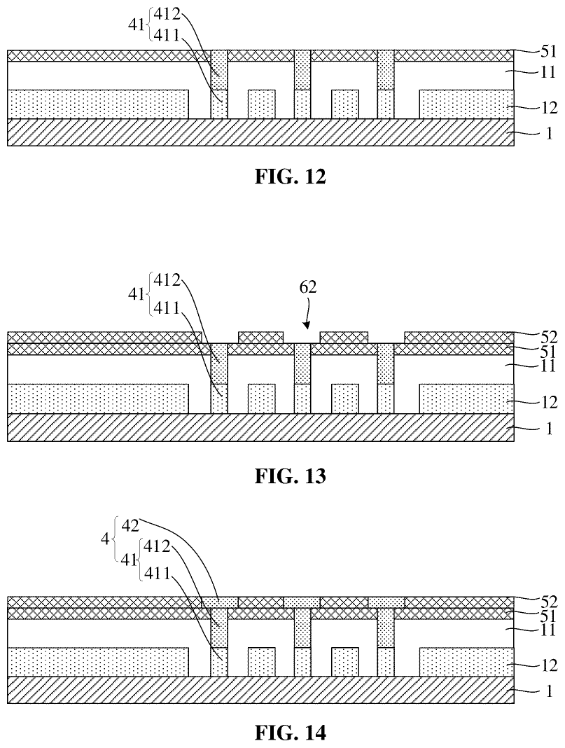

With reference to FIG. 12, a plurality of second welding pads 412 are formed in the solder resist layer 11 and the plurality of first openings 61, where each of the plurality of second welding pads 412 is connected to a respective one of the plurality of first welding pads 411. Each of the plurality of second welding pads 412 and the respective one of the plurality of first welding pads 411 constitute a respective one of a plurality of bottom layer welding pads 41. Exemplarily, copper with a specified thickness is plated in the solder resist layer 11 and the plurality of first openings 61 using an electroplating process.

With reference to FIG. 13, a second mask layer 62 is formed, where the second mask layer 62 is provided with a plurality of second openings 62. The width of each of the plurality of second openings is greater than the width of each of the plurality of first openings. Each of the plurality of second openings 62 directly faces toward a respective one of the plurality of second welding pads 412 and exposes a top surface of the respective one of the plurality of second welding pads 412.

Exemplarily, the second mask layer 52 may be a second photoresist layer. That is, the second photoresist layer is spin-coated on the first photoresist layer, and photolithographic processing is performed on the second photoresist layer to form the plurality of second openings 62. In some other embodiments, after the first photoresist layer is removed, the second photoresist layer is spin-coated.

With reference to FIG. 14, a plurality of top layer welding pads 42 are formed in the plurality of second openings 62, where each of the plurality of top layer welding pads 42 is connected to a respective one of the plurality of bottom layer welding pads 41, and each of the plurality of top layer welding pads 42 and the respective one of the plurality of bottom layer welding pads 41 constitute a respective one of the plurality of welding pads 4. Exemplarily, copper with a specified thickness is plated in the plurality of second openings 62 using an electroplating process.

After the plurality of top layer welding pads 42 are formed, the first mask layer 51 and the second mask layer 52 are removed, so that the bottom surface of the protruding part of each of the plurality of top layer welding pads 42 can be exposed.

At this point, based on the process operations shown in FIG. 8 to FIG. 14, the plurality of welding pads 4 are formed on the surface of the substrate 1. Each of the plurality of welding pads 4 includes a bottom layer welding pad 41 and a top layer welding pad 42 which are stacked onto one another, and at least two of the peripheral surfaces of the top layer welding pad 42 are protruded relative to the peripheral surfaces of the bottom layer welding pad 41. It is to be noted that the bottom layer welding pad 41 formed by the process operations shown in FIG. 8 to FIG. 14 are in contact with the solder resist layer 11. In some other embodiments, a gap may be formed between the bottom layer welding pad 41 and the solder resist layer 11. Detailed description will be made below.

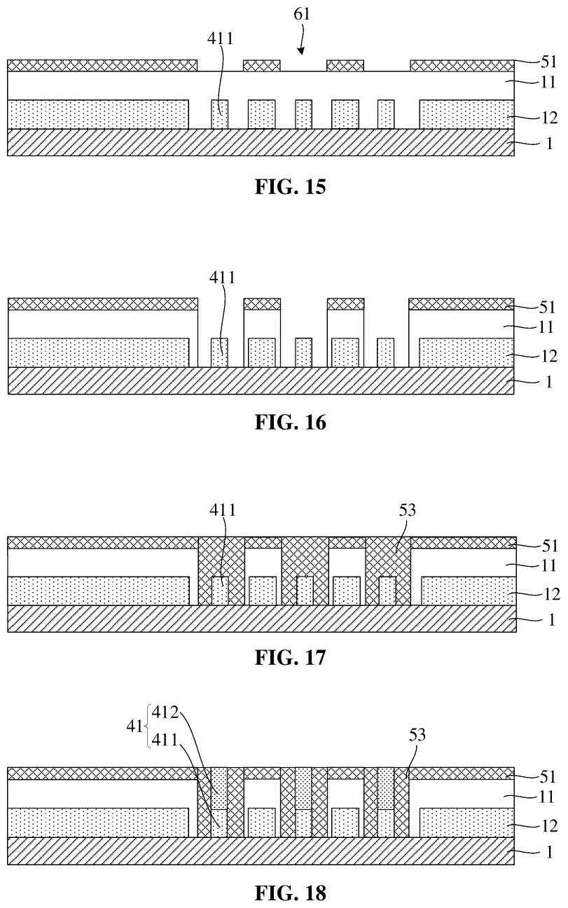

With reference to FIG. 15, a first mask layer 51 is formed on the solder resist layer 11, where the first mask layer 51 is provided with a plurality of first openings 61, and the width of each of the plurality of first openings 61 is slightly greater than the width of each of the subsequently formed second welding pads 412.

With reference to FIG. 16, the solder resist layer 11 is removed along the plurality of first openings 61, that is, the solder resist layer 11 located on a top surface and a peripheral surface of each of the plurality of first welding pads 411 is removed. It is to be noted that in some other embodiments, the solder resist layer 11 located on the peripheral surface of each of the plurality of first welding pads 411 may not be removed (that is, may be retained), but only the solder resist layer 11 located on the top surface of each of the plurality of first welding pads 411 is removed, and the width of the removed solder resist layer 11 is greater than the width of each of the plurality of first welding pads 411, so that a gap may be formed between each of the subsequently formed second welding pads 412 and the solder resist layer 11.

With reference to FIG. 17, a third mask layer 53 covering the plurality of first welding pads 411 is formed, where the third mask layer 53 also fills a gap between each of the plurality of first welding pads 411 and the solder resist layer 11. Exemplarily, a third photoresist layer is applied on the plurality of first welding pads 411 as the third mask layer 53. In addition, the third mask layer 53 may also be formed after the first mask layer 51 is removed. It is to be noted that in other embodiments, if the solder resist layer 11 located on the peripheral surface of each of the plurality of first welding pads 411 is not removed (that is, is retained), the third mask layer 53 is located above the plurality of first welding pads 411 and does not cover the peripheral surface of each of the plurality of first welding pads 411.

With reference to FIG. 18, the third mask layer 53 is patterned to form a plurality of third openings, where each of the plurality of third openings is located directly above a respective one of the plurality of first welding pads 411. The third mask layer 53 is removed along the plurality of third openings to expose the top surface of each of the plurality of first welding pads 411. Thereafter, the plurality of second welding pads 412 are formed on the plurality of first welding pads 411.

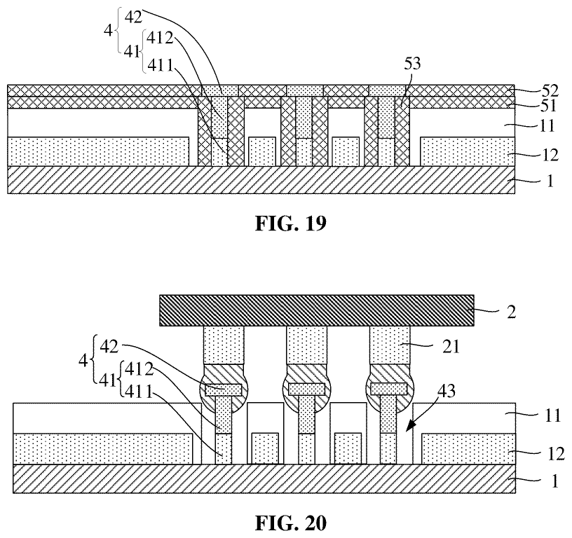

With reference to FIG. 19, a second mask layer 52 is formed, where the second mask layer 52 is located on the first masker lay 51 and the third mask layer 53, and the second mask layer covers the plurality of bottom layer welding pads 41. In some embodiments, after the first mask layer 51 and the third mask layer 53 are removed, the second mask layer 52 is formed on the top surface of the solder mask layer 11 and in the gap between the solder resist layer 11 and each of the plurality of bottom layer welding pads 41. The second mask layer 52 is provided with a plurality of second openings 62 (with reference to FIG. 13), each of the plurality of second openings 62 is located directly above a respective one of the plurality of bottom layer welding pads 41, and the width of each of the plurality of second openings 62 is greater than the width of each of the plurality of bottom layer welding pads 41. The plurality of top layer welding pads 42 are formed in the plurality of second openings 62.

With reference to FIG. 20, after the plurality of welding pads 4 are formed, the first mask layer 51, the second mask layer 52, and the third mask layer 53 are removed, to expose the plurality of welding pads 4 and the gap 43 between the solder resist layer 11 and each of the plurality of bottom layer welding pads 41. It is to be noted that in some other embodiments, if the solder resist layer 11 located on the peripheral surface of each of the plurality of first welding pads 411 is not removed, the gap 43 is only located between the solder resist layer 11 and each of the plurality of second welding pads 412.

With further reference to FIG. 20, a chip 2 is provided. The chip 2 is welded to the plurality of welding pads 4 by the plurality of solder balls 3, and each of the plurality of solder balls 3 wraps a respective one of the plurality of top layer welding pads 42. That is, solders are melted under a high temperature condition so that the solders diffuse and connect the plurality of top layer welding pads 42 and the chip 2 with each other, to form the plurality of solder balls 3. Each of the plurality of solder balls 3 is in contact with the top surface, the peripheral surfaces, and part of the bottom surface of a respective one of the plurality of top layer welding pads 42.

In summary, different mask layers are provided with different openings, so that the plurality of bottom layer welding pads 41 have different dimensions than the plurality of top layer welding pads 42. That is, the peripheral surfaces of each of the plurality of top layer welding pads 42 are protruded relative to the peripheral surfaces of a respective one of the plurality of bottom layer welding pads 41, to form the plurality of welding pads 4 which are three-dimensional, thereby saving the spatial position of the substrate 1 and improving the reliability of the soldering.

In the descriptions of the specification, the descriptions made with reference to terms “some embodiments”, “exemplarily”, and the like refer to that specific features, structures, materials or characteristics described in combination with the embodiment or the example are included in at least one embodiment or example of the disclosure. In the specification, these terms are not always schematically expressed for the same embodiment or example. Moreover, the specific described features, structures, materials or characteristics may be combined in a proper manner in any one or more embodiments or examples. In addition, those skilled in the art may integrate and combine different embodiments or examples described in the specification and features of different embodiments or examples without conflicts.

The embodiments of the disclosure have been shown or described above. However, it can be understood that the abovementioned embodiments are exemplary and should not be understood as limits to the disclosure, and those of ordinary skill in the art may make variations, modifications, replacements, transformations to the abovementioned embodiments within the scope of the disclosure, it is therefore intended that all variations or modifications made in light of the claims and specification of the disclosure fall within the scope of the disclosure.

What is claimed is:

1. A package structure, comprising:
a substrate, wherein at least one welding pad is disposed on a surface of the substrate, the at least one welding pad comprising a bottom layer welding pad and a top layer welding pad which are stacked onto one another, and at least two of peripheral surfaces of the top layer welding pad being protruded relative to peripheral surfaces of the bottom layer welding pad;
a chip located on the substrate and spaced apart from the substrate; and
at least one solder ball, wherein the at least one solder ball is welded to the substrate and the chip, and the at least one solder ball wraps the top layer welding pad.

2. The package structure of claim 1, wherein
two of the peripheral surfaces of the top layer welding pad located on two opposite sides of the top layer welding pad are protruded relative to two of the peripheral surfaces of the bottom layer welding pad located on two opposite sides of the bottom layer welding pad; or
all the peripheral surfaces of the top layer welding pad are protruded relative to all the peripheral surfaces of the bottom layer welding pad.

3. The package structure of claim 2, wherein an orthographic projection of the bottom layer welding pad on the surface of the substrate is located at a center within an orthographic projection of the top layer bonding pad on the surface of the substrate.

4. The package structure of claim 1, wherein a solder resist layer is disposed on the surface of the substrate, the bottom layer welding pad penetrates through the solder resist layer, and a bottom surface of the top layer welding pad is located higher than a top surface of the solder resist layer.

5. The package structure of claim 4, wherein the package structure comprises a plurality of welding pads, and the solder resist layer is located between any adjacent bottom layer welding pads of bottom layer welding pads of the plurality of welding pads.

6. The package structure of claim 4, wherein a difference between a height of the bottom surface of the top layer welding pad and a height of the top surface of the solder resist layer ranges from 3 um to 7 um.

7. The package structure of claim 4, wherein a gap is formed between the solder resist layer and the bottom layer welding pad.

8. The package structure of claim 7, wherein the peripheral surfaces of the top layer welding pad are protruded by a distance less than or equal to a width of the gap relative to the peripheral surfaces of the bottom layer welding pad.

9. The package structure of claim 1, wherein at least one support bump is disposed on a surface of the chip facing toward the substrate, and the at least one welding ball is connected to the at least one support bump.

10. The package structure of claim 9, wherein a width of the at least one support bump is greater than a width of the top layer welding pad.

11. The package structure of claim 10, wherein a difference between the width of the at least one support bump and the width of the top layer welding pad is greater than 10 um.

12. The package structure of claim 1, wherein a difference between a width of the top layer welding pad and a width of the bottom layer welding pad is greater than 10 um.

13. The package structure of claim 12, wherein the width of the bottom layer welding pad is greater than 12 um.

14. The package structure of claim 1, wherein a thickness of the top layer welding pad ranges from 5 um to 10 um.

15. The package structure of claim 1, wherein the bottom layer welding pad comprises a first welding pad and a second welding pad which are stacked onto one another;
wherein a plurality of conductive layers are disposed on the surface of the substrate and spaced apart from each other, and the plurality of conductive layers are disposed on a same layer as the first welding pad and spaced apart from the first welding pad;
wherein a solder resist layer is disposed on the surface of the substrate, and covers the plurality of conductive layers.

16. The package structure of claim 15, wherein the package structure comprises a plurality of welding pads, and at least one conductive layer is disposed between any adjacent first welding pads of first welding pads.

17. A method for manufacturing a package structure, comprising:
providing a substrate, and forming a plurality of welding pads on a surface of the substrate, wherein each of the plurality of welding pads comprises a bottom layer welding pad and a top layer welding pad which are stacked onto one another, and at least two of peripheral surfaces of the top layer welding pad are protruded relative to peripheral surfaces of the bottom layer welding pad;
providing a chip; and
welding the chip to the plurality of welding pads through a plurality of solder balls, wherein each of the plurality of solder balls wraps a respective one of the top layer welding pads.

18. The method for manufacturing the package structure of claim 17, wherein forming the plurality of welding pads comprises:
forming an initial conductive layer, and patterning the initial conductive layer to form a plurality of first welding pads;
forming a solder resist layer covering the plurality of first welding pads;
forming a first mask layer on the solder resist layer, wherein the first mask layer is provided with a plurality of first openings directly facing toward the plurality of first welding pads;
removing the solder resist layer located on a top surface of the first welding pad along the plurality of first openings;
forming a plurality of second welding pads in the solder resist layer and the plurality of first openings, wherein each of the plurality of second welding pads is connected to a respective one of the plurality of first welding pads, and each of the plurality of second welding pads and the respective one of the plurality of first welding pads constitute a respective one of the bottom layer welding pads;
forming a second mask layer, wherein the second mask layer is provided with a plurality of second openings, a width of each of the plurality of second openings is greater than a width of each of the plurality of first openings, and each of the plurality of second openings directly faces toward a respective one of the plurality of second welding pads and exposes a top surface of the respective one of the plurality of second welding pads; and
forming a plurality of top layer welding pads in the plurality of second openings, wherein each of the plurality of top layer welding pads is connected to a respective one of the bottom layer welding pads, and each of the plurality of top layer welding pads and the respective one of the bottom layer welding pads constitute a respective one of the plurality of welding pads.
